(19) United States
(12) Patent Application Publication
(10) Pub. No.: US 2011/0297202 A1
(43) Pub. Date: Dec. 8, 2011

(54) NANO STRUCTURE INCLUDING DISCONTINUOUS AREA AND THERMOELECTRIC DEVICE INCLUDING NANO STRUCTURE

(75) Inventors: Eun-kyung LEE, Yongin-si (KR); Byoung-lyong CHOI, Yongin-si (KR); Jun-ho LEE, Yongin-si (KR); Dong-mok WHANG, Seoul (KR); Jong-woon LEE, Busan (KR)

(73) Assignee: SAMSUNG ELECTRONICS CO., LTD., Suwon-si (KR)

(21) Appl. No.: 13/114,887

(22) Filed: May 24, 2011

(30) Foreign Application Priority Data
Jun. 7, 2010 (KR) 10-2010-0053598

(51) Int. Cl. H01L 35/14; H01B 1/02; H01B 1/04; H01B 1/20; B82Y 30/00; B82Y 99/00; H01L 35/34

(52) U.S. Cl. 136/238; 252/500; 252/512; 252/519.4; 252/518.1; 252/521.5; 977/948; 136/201; 977/700

(57) ABSTRACT

A thermoelectric material including: a nanostructure; a discontinuous area disposed in the nanostructure, and an uneven portion disposed on the nano structure.

### CROSS-REFERENCE TO RELATED APPLICATIONS

This application claims priority to Korean Patent Application No. 10-2010-0053598, filed on Jun. 7, 2010, and all the benefits accruing therefrom under 35 U.S.C. §119, the content of which in its entirety is herein incorporated by reference.

### BACKGROUND

1. Field

The present disclosure relates to nano structures including a discontinuous area, and thermoelectric devices including the nano structures.

2. Description of the Related Art

A thermoelectric device can convert thermal energy into electrical energy, or vice versa. In the Seebeck effect, electricity is generated from a temperature difference between ends of a thermoelectric material. Alternatively, in the Peltier effect, if electrical current is applied to the thermoelectric material, a temperature gradient is generated between ends of the thermoelectric material. Thermal energy, such as that produced in a computer or in an automobile engine, may be converted into electrical energy using the Seebeck effect, and various cooling systems may be implemented without a need for a refrigerant using the Peltier effect. As interests in new sources of energy, waste energy recovery, environmental protection, or the like have increased, thermoelectric devices have also attracted much attention.

The efficiency of a thermoelectric device may be characterized using the dimensionless figure of merit ZT. ZT is a performance coefficient of a thermoelectric material. The ZT coefficient may be expressed as in Equation 1.

$$Z T = \frac{{S}^{2} σ}{k} T \qquad ( 1 )$$

According to Equation 1, the ZT coefficient is proportional to a Seebeck coefficient S of the thermoelectric material and an electrical conductivity σ, and is inversely proportional to a thermal conductivity k. The Seebeck coefficient S represents a thermoelectric voltage per unit temperature change across a material (i.e., dV/dT). The Seebeck coefficient S, the electric conductivity σ, and the thermal conductivity k are interrelated, and thus, they may not be varied independently of one another. As a result, it is difficult to provide a thermoelectric material with an improved ZT coefficient, and a thermoelectric device having improved efficiency. Accordingly there remains a need for improved thermoelectric devices and materials having an improved figure of merit ZT.

### SUMMARY

Provided is a nano structure including a discontinuous area.

Provided is a thermoelectric device including the nano structure including the discontinuous area.

Additional aspects, features, and advantages will be set forth in part in the description which follows and, in part, will be apparent from the description.

According to an aspect, a thermoelectric material includes a nanostructure; a discontinuous area disposed in the nano structure; and an uneven portion disposed on the nano structure.

The nano structure may include a crystalline structure, and the discontinuous area may be disposed in the crystalline structure.

The nano structure may have at least one of a nano rod shape, a nano wire shape, a tapered shape, a nano ribbon shape, or a nano belt shape, and the nano structure may include at least one of a core-shell structure or a nano tube structure.

The nano structure may include the core-shell structure, and the discontinuous area may be disposed in at least one of the core and shell.

The core and the shell may include materials having different lattice constants.

The nano structure may include at least one of a Group IV semiconductor material, a Groups III-V semiconductor material, a Groups II-VI semiconductor material, an oxide, a nitride, or a polymeric material.

According to another aspect, a thermoelectric device includes a first region and a second region; a first thermoelectric body disposed between the first region and the second region; and a second thermoelectric body disposed between the first region and the second region, wherein at least one of the first thermoelectric body and the second thermoelectric body includes a discontinuous area, and an uneven portion disposed on a surface of the at least one thermoelectric body.

Also disclosed is a method of preparing a thermoelectric material, the method including: contacting a catalyst with a first gas to form a core; contacting the core with a second gas to form a shell on the core to form a nanostructure; and disposing a crystallographic defect in a discontinuous area of the shell of the nanostructure to form an uneven portion on a surface of the nanostructure to form the thermoelectric material.

### BRIEF DESCRIPTION OF THE DRAWINGS

These and/or other aspects will become apparent and more readily appreciated from the following description of the embodiments, taken in conjunction with the accompanying drawings in which:

FIGS. 1A through 1D are cross-sectional views of an embodiment of a nano structure including a discontinuous area;

FIGS. 2A and 2B are a diagrams of an embodiment of a nano structure having a tapered shape and including a discontinuous area;

FIG. 3 is a diagram of an embodiment of a nano structure having a nano ribbon shape or a nano belt shape and including a discontinuous area;

FIGS. 4A through 4D are diagrams of an embodiment of a method of manufacturing a nano structure including a discontinuous area; and

FIG. 5 is a cross section diagram of an embodiment of a thermoelectric device.

### DETAILED DESCRIPTION

The invention now will be described more fully hereinafter with reference to the accompanying drawings, wherein like reference numerals refer to the like elements throughout, and the thicknesses of layers and regions are exaggerated for clarity. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer, or section from another element, component, region, layer, or section. Thus, “a first element,” “component,” “region,” “layer,” or “section” discussed below could be termed a second element, component, region, layer, or section without departing from the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

“Group” means a group of the periodic table of the elements.

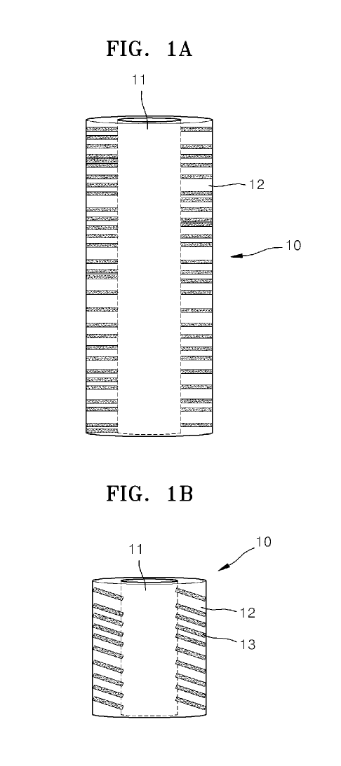

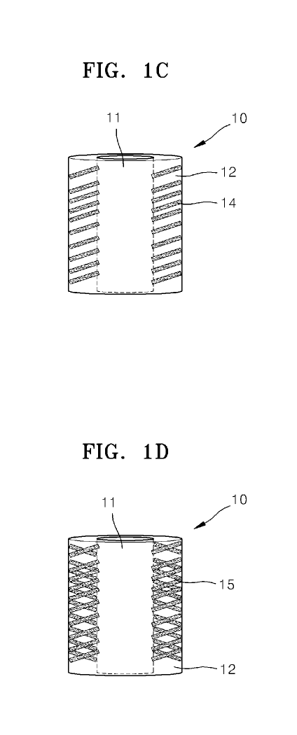

FIGS. 1A through 1D are cross-sectional views of an embodiment of a nano structure 10 including a discontinuous area.

Referring to FIG. 1A, the nano structure 10 includes a core 11 and a shell 12. A discontinuous area is present in the nano structure 10. The discontinuous area may comprise a plurality of one-dimensional or two-dimensional crystallographic defects. For example, the crystallographic defects may comprise at least one of a linear defect, or a surface defect. The discontinuous area may be disposed on both the core 11 and the shell 12 of the nano structure 10, or alternatively, may be only on the shell 12, or only on the core 11. For example, the core 11 may be crystalline, and the shell 12 may comprise a crystalline structure including a discontinuity, e.g., an edge dislocation, a screw dislocation, or other a discontinuous crystalline structure. In addition, the core 11 may comprise a discontinuous crystalline structure including a discontinuous area disposed therein, and the shell 12 may have a crystalline structure.

The crystallographic defects may comprise a point defect, such as a vacancy defect, an interstitial defect, or an antisite defect, or a linear defect, such as an edge or screw dislocation. Also, the crystallographic defect may comprise a planar defect, such as a stacking fault.

The discontinuous area may comprise a plurality of crystallographic defects and be disposed in the nano structure 10. The crystallographic defects in the nano structure 10 may be generated due to differences between a material of the core 11 and a material of the shell 12, or differences between crystalline structures of the core 11 and the shell 12. For example, when a crystal comprises materials having different lattice constants, a lattice distortion occurs due to a difference between the lattice constants, and thus, a strain is caused by the lattice distortion. The accumulated strain may generate a dislocation in the nano structure 10.

A discontinuous area on a surface of the nano structure 10 may be disposed according to the type of dislocation in the nano structure 10. For example, the dislocation in the nano structure 10 may cause an uneven structure having a step or terrace shape on an external surface of the nano structure 10. The step or terrace shape may be the result of at least one of an edge dislocation, a screw dislocation, or the like. As is further disclosed above, the discontinuous area in the nano structure 10 comprises a crystallographic defect that may cause a discontinuous area on a surface of the nano structure 10. Thus, in an embodiment, the nano structure includes the discontinuous area formed therein, and an uneven structure may be formed on a surface of the nano structure by the discontinuous area disposed in the nano structure.

The discontinuous area of the nano structure 10 may have various shapes and/or orientations. As shown in FIG. 1A, the discontinuous area may be disposed in a direction perpendicular to an interface between the core 11 and the shell 12. As shown in FIGS. 1B and 1C, a direction of the discontinuous area 13 that is disposed in the shell 12 may be a diagonal direction with respect to an interface between the core 11 and the shell 12. Also, as shown in FIG. 1D, a direction of a discontinuous area 15 in the shell 12 may comprise various directions, and thus the discontinuous area 15 may have a complex shape, such as a helical or zigzag shape. Thus in an embodiment, the nano structure 10 may comprise a first discontinuous area oriented in a first direction, and a second discontinuous area oriented in a second direction. The first and second directions may form an oblique angle, and the first and second directions may form an obtuse angle. In addition, a plurality of discontinuous areas in the nano structure 10 may have various crystallographic orientations. Thus, for example, a first discontinuous area may have a first crystallographic orientation, and a second discontinuous area may have a second crystallographic orientation, and the first and the second crystallographic orientations may be different and may each independently be different than a crystallographic orientation of the nano structure 10. In addition, a shape of the discontinuous area need not be a straight shape, and the discontinuous area may have a curved or modulated shape, for example.

The nano structure 10 may have at least one of a nano rod shape, a nano wire shape, a tapered shape, a nano ribbon shape, or a nano belt shape. As shown in FIGS. 1A through 1D, the nano structure 10 comprises the core 11 and the shell 12. Alternatively, the nano structure 10 may have a nano tube shape, wherein a space is defined inside the core 11 as shown in FIGS. 1A through 1D.

In an embodiment, the discontinuous area is disposed in a predetermined region of the nano structure 10. A longitudinal and a latitudinal dimension of the nano structure 10 may each independently be about 0.1 micrometer (μm) to about 10 millimeters (mm), specifically about 1 μm to about 1 mm, more specifically about 10 μm to about 0.1 mm. Also, the discontinuous area may have a dimension of about 1 nm to about 500 nm, specifically about 2 nm to about 400 nm, more specifically about 4 nm to about 300 nm. While not wanting to be bound by theory, it is understood that because the discontinuous area may have a dimension of about 1 nm to about 50 nm, specifically about 2 nm to about 40 nm, more specifically about 4 nm to about 30 nm, electron transport is essentially unimpeded by the discontinuous area, whereas the size of the discontinuous area is sufficient to scatter phonons. Because phonons are preferentially scattered by the discontinuous area, movement of electric charges and phonons that move through the nano structure 10 may be independently controlled. Thus the thermal conductivity of the nano structure can be reduced without significantly reducing electrical conductivity. Returning to Formula I, reducing the thermal conductivity k of a material while not substantially altering the electrical conductivity a provides for an increase in ZT. When ZT is increased, the practical utility of the nano structure 10 is increased.

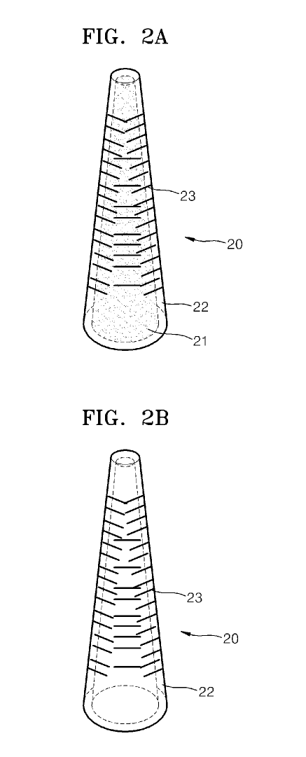

FIG. 2 is a diagram of an embodiment of a nano structure 20 having a tapered shape and comprising a discontinuous area 23 disposed therein. The tapered shape is tapered in a longitudinal direction of the nano structure 20.

Referring to FIG. 2, the nano structure 20 having the tapered shape includes a core 21 and a shell 22. A discontinuous area 23 is disposed in the shell 22. As disclosed above, the discontinuous area 23 comprises a crystallographic defect and is disposed in the nano structure 20. An uneven portion, such as a portion having a step difference or a terrace shape, may be disposed on an external surface of the nano structure 20. Also, the core 21 may define a space, and in an embodiment, the nano structure 20 may be a nano tube. Alternatively, the discontinuous area 23 may be disposed only in the shell 22.

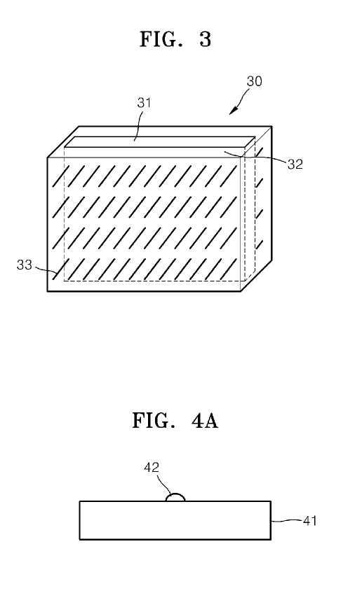

FIG. 3 is a diagram of an embodiment of a nano structure 30 having a nano ribbon shape or a nano belt shape and including a discontinuous area 33.

Referring to FIG. 3, the nano structure 30 includes a core 31, and a shell 32 is disposed on at least two surfaces of the core 31. The discontinuous area 33 is disposed in the shell 32. In an embodiment, the at least two surfaces of the core 31 comprise a first surface and an opposite second surface of the core 31.

As further disclosed above, the nano structure may have various shapes, such as at least one of a nano wire, a nano rod, a nano ribbon, a nano belts, or the like, and may comprise a core-shell structure not defining an inner space, or may comprise a nano tube structure defining an inner space. In addition, a cross section of the nano structure may be at least one of a circular, spherical, or elliptical shape, or may have a polygonal cross section, such as a triangular, square, or hexagonal cross section.

The nano structure may include at least one of a Group IV semiconductor material, a Groups III-V semiconductor material, a Groups II-VI semiconductor material, an oxide, a nitride, or a polymeric material. The core and the shell may each independently include at least one of a Group IV semiconductor material, a Groups III-V semiconductor material, an oxide, a nitride, or a polymeric material. Thus the core and the shell may comprise different materials.

The Group IV semiconductor material may comprise at least one of Si, Ge, or C. A silicon germanium compound can be mentioned.

Representative Groups III-V semiconductor materials include InN, GaN, AlN, GaAs, InP, InAs, GaP, InSb, GaSb, and ternary or quaternary alloys or compounds thereof. Representative ternary compounds include InGaAs, and InAsSb. A ratio of the Group V element to the Group III element in the Groups III-V semiconductor material may be 0.8 to about 1.2, specifically about 0.9 to about 1.1, more specifically about 1.

Representative Groups II-VI semiconductor materials include CdTe, CdSe, CdS, ZnTe, ZnSe, or ZnS, and ternary or quaternary alloys or compounds thereof. A ratio of the Group VI element to the Group II element in the Groups II-VI semiconductor material may be about 0.8 to about 1.2, specifically about 0.9 to about 1.1, more specifically about 1.

The polymeric material may comprise at least one of a thermoplastic or a thermoset. The thermoplastic may comprise at least one of a polyacetal, polyolefin, polyacrylic, polycarbonate, polystyrene, polyester, polyamide, polyamideimide, polyarylate, polyarylsulfone, polyethersulfone, polyphenylene sulfide, polyvinyl chloride, polysulfone, polyimide, polyetherimide, polytetrafluoroethylene, polyetherketone, polyether etherketone, polyether ketone ketone, polybenzoxazole, polyphthalide, polyacetal, polyanhydride, polyvinyl ether, polyvinyl thioether, polyvinyl alcohol, polyvinyl ketones, polyvinyl halide, polyvinyl nitrile, polyvinyl esters polysulfonate, polysulfide, polythioester, polysulfone, polysulfonamide, polyurea, a fluorinated polymer, or a polycarbonate. Representative thermosets include vulcanized rubber, a phenol-formaldehyde, a urea-formaldehyde, a urethane, a melamine, a polyester, a polyimides, or a silicone. A combination comprising at least one of the foregoing can be used.

The discontinuous area in the nano structure may be formed by controlling the type and composition ratio of materials, or may be formed by forming the core-shell with different materials.

For example, in an embodiment wherein the nano structure comprises SiGe will be further disclosed. Ge and Si are both semiconductors. Because Ge has electron or hole mobility ten times higher than that of Si, and a smaller band gap (Eg=0.66 electron volts, eV) than Si, Ge is widely used as an optical director. The thermal conductivities of Si and Ge in a bulk material are 148 watts per milliKelvin (W/mK) and 58 W/mK, respectively. However, when Si and Ge constitute a SiGe structure, transmission of phonons is interrupted by a size-difference between Si and Ge atoms, and thus the thermal conductivity of Si_{0.5}Ge_{0.5} is reduced to 8.3 W/mK. The composition or structure in the SiGe crystal structure may vary according to a content of Si and Ge in the SiGe structure. When a composition difference between Si and Ge is significant, strain may occur in the material, and the strain may cause small defects in the nano structure. A dislocation may be generated due to the defects, and a discontinuous area may be formed on a surface of the nano structure according to behavior of the dislocation.

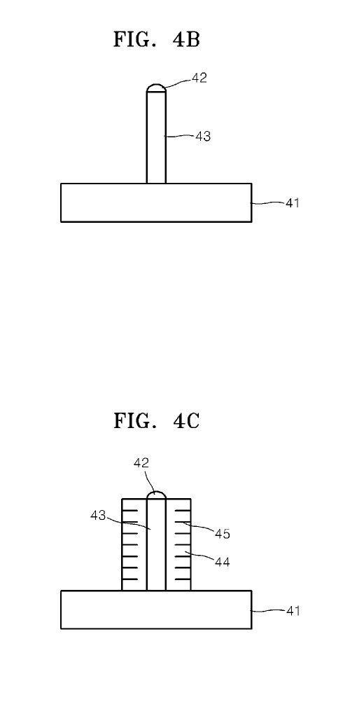

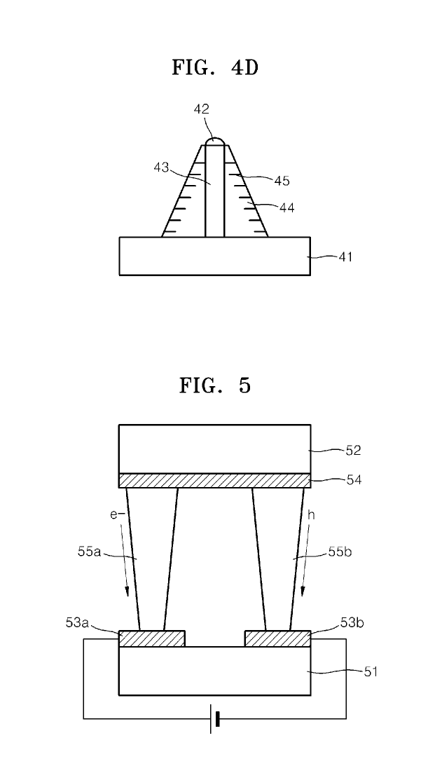

FIGS. 4A through 4D are diagrams explaining an embodiment of a method of manufacturing a nano structure including a discontinuous area.

Referring to FIG. 4A, a catalyst material 42 for forming the nano structure is disposed on a lower structure 41, such as a substrate.

Referring to FIG. 4B, the catalyst material 42 is contacted with a gas for nano structure growth to grow a core 43. If the core 43 is to comprise silicon (Si), the catalyst material 42 may be silver (Au), or the like, and a Si precursor gas (a Si-containing gas, e.g., SiH₄) may be supplied as the gas for nano structure growth. In an embodiment, different gases may be optionally also supplied to facilitate lateral growth of the core 42. Then, after the core 42 is grown, the discontinuous area may be formed due to a difference in crystallization properties between the core and shell materials.

Referring to FIG. 4C or 4D, a gas for shell growth is supplied to form a shell 44 along a lateral direction of the core 43. When the shell 44 is to comprise Ge, the core 42 may be contacted with a Ge precursor gas (a Ge-containing gas, e.g., GeH₄). In FIG. 4C, the nano structure is grown in a nano wire shape or a nano tube shape. In FIG. 4D, the nano structure is grown in a tapered shape. In an embodiment wherein the shell 44 comprising Ge is formed on the core 43 comprising Si, a tapered nano structure may be formed by growing the shell 44 at a higher temperature than a temperature at which a nano rod or nano wire structure is formed.

In order to obtain a nano tube structure, the core 43 of the nano structure of FIG. 4C or 4D may be selectively removed by etching so that only the shell 44 remains therein, thereby forming the nano tube structure including a discontinuous area.

As further disclosed above, a nano structure including a discontinuous area disposed in or on the nano structure may be used in various devices. The nano structure including the discontinuous area may be used in a high-efficiency and highly integrated thermoelectric device, an optical device, a photosensitive sensor, or a solar cell, or the like, for example.

FIG. 5 is a cross section diagram of an embodiment of a thermoelectric device.

Referring to FIG. 5, the thermoelectric device includes a first region 51, a second region 52, and first and second thermoelectric bodies 55a and 55b, respectively, wherein at least one of the first and the second thermoelectric bodies includes a discontinuous area disposed between the first region 51 and the second region 52. In an embodiment, a first electrode 53a may be disposed between the first thermoelectric body 55a and the first region 51, and a second electrode 53b may be disposed between the second thermoelectric body 55b and the first region 51. A common electrode 54 may be disposed between the first and the second thermoelectric bodies 55a and 55b, and the second region 52. Each or both of the first and the second thermoelectric bodies 55a and 55b, respectively, are configured as a nano structure including a discontinuous area. The discontinuous area may remarkably increase a phonon scattering effect, thereby reducing thermal conductivity of the thermoelectric device.

For reference, a temperature of the first region 51 may be the same as or different than a temperature of the second region 52. The first region 51 may be a high-temperature region having a temperature higher than that of the second region 52, and the second region 52 may be a low-temperature region. Alternatively, the first region 51 may be a low-temperature region having a temperature lower than that of the second region 52, and the second region 52 may be a high-temperature region. In an embodiment wherein no temperature difference is provided between the first region 51 and the second region 52, power may be supplied from an external power source to the thermoelectric device so that the thermoelectric device may be used as a thermoelectric cooling device to provide a temperature difference between the first region 51 and the second region 52. In addition, when the temperatures of the first region 51 and the second region 52 are different, the thermoelectric device may be used as a thermoelectric generator to generate electrical current (comprising electrons e⁻ and holes h⁺) due to the temperature difference between the first region 51 and the second region 52.

As disclosed above, according to an embodiment, a nano structure may comprise a discontinuous area comprising a crystallographic defect that is intentionally disposed in the nano structure.

In addition, the thermal properties of a thermoelectric device may be improved by using a thermoelectric body including the discontinuous area.

It should be understood that the exemplary embodiments described herein shall be considered in a descriptive sense only and not for purposes of limitation. Descriptions of features or aspects within each embodiment should be considered as available for other similar features or aspects in other embodiments.

What is claimed is:

1. A thermoelectric material comprising:
a nano structure;
a discontinuous area disposed in the nano structure; and
an uneven portion disposed on the nano structure.

2. The thermoelectric material of claim 1, wherein the nano structure comprises a crystalline structure, and wherein the discontinuous area is disposed in the crystalline structure.

3. The thermoelectric material of claim 1, wherein the nano structure has at least one of a nano rod shape, a nano wire shape, a tapered shape, a nano ribbon shape, or a nano belt shape, and
wherein the nano structure comprises at least one of a core-shell structure or a nano tube structure.

4. The thermoelectric material of claim 3, wherein the nano structure comprises the core-shell structure, and
wherein the discontinuous area is disposed in at least one of the core and shell.

5. The thermoelectric material of claim 4, wherein the core comprises a first material having a first lattice constant, the shell comprises a second material having a second lattice constant, and the first and the second lattice constants are different.

6. The thermoelectric material of claim 1, wherein the nano structure comprises at least one of a Group IV semiconductor material, a Groups III-V semiconductor material, a Groups II-VI semiconductor material, an oxide, a nitride, or a polymeric material.

7. The thermoelectric material of claim 6, wherein the Group IV semiconductor material comprises Si or Ge, the Groups III-V semiconductor material comprises InN, GaN, AlN, GaAs, InP, InAs, GaP, InSb, GaSb, or ternary or quaternary alloys or compounds thereof, and the Groups II-VI semiconductor material comprises CdTe, CdSe, CdS, ZnTe, ZnSe, ZnS, or ternary or quaternary alloys or compounds thereof.

8. The thermoelectric material of claim 1, wherein the nano structure has a dimension of about 0.1 micrometer to about 10 millimeters.

9. The thermoelectric material of claim 1, wherein the discontinuous area has a dimension of about 1 nanometer to about 50 nanometers.

10. The thermoelectric material of claim 1, wherein the discontinuous area has a dimension sufficient to scatter a phonon and substantially insufficient to scatter an electron.

11. A thermoelectric device comprising:
a first region and a second region;
a first thermoelectric body disposed between the first region and the second region; and
a second thermoelectric body disposed between the first region and the second region,
wherein at least one of the first thermoelectric body and the second thermoelectric body comprises
a discontinuous area, and
an uneven portion disposed on a surface of the at least one thermoelectric body.

12. The thermoelectric device of claim 11, wherein the discontinuous area has a dimension of about 1 nanometer to about 50 nanometers.

13. The thermoelectric device of claim 11, wherein at least one of the first thermoelectric body and the second thermoelectric body comprises a nano structure comprising a crystalline structure, and
wherein the discontinuous area is disposed on the crystalline structure.

14. The thermoelectric device of claim 13,
wherein the nano structure has at least one of a nano rod shape, a nano wire shape, a tapered shape, a nano ribbon shape, or a nano belt shape, and
wherein the nano structure comprises a core-shell structure or a nano tube structure.

15. The thermoelectric device of claim 14, wherein the core comprises a first material having a first lattice constant, the shell comprises a second material having a second lattice constant, and the first and the second lattice constants are different.

16. The thermoelectric device of claim 11,
wherein at least one of the first thermoelectric body and the second thermoelectric body comprises a nano structure comprising a core-shell structure, and
wherein the discontinuous area is disposed in at least one of the core and shell.

17. The thermoelectric device of claim 13, wherein the nano structure has a dimension of about 0.1 micrometer to about 10 millimeters.

18. The thermoelectric device of claim 13, wherein the nano structure comprises at least one of a Group IV semiconductor material, a Groups III-V semiconductor material, a Groups II-VI semiconductor material, an oxide, a nitride, or a polymeric material.

19. The thermoelectric device of claim 11, further comprising a first electrode disposed between the first region and the first thermoelectric body and a second electrode disposed between the first region and the second thermoelectric body.

20. A method of preparing a thermoelectric material, the method comprising:
contacting a catalyst with a first gas to form a core;
contacting the core with a second gas to form a shell on the core to form a nanostructure; and
disposing a crystallographic defect in a discontinuous area of the shell of the nanostructure to form an uneven portion on a surface of the nanostructure to form the thermoelectric material.
